(19) United States
(12) Patent Application Publication
(10) Pub. No.: US 2024/0145155 A1
(43) Pub. Date: May 2, 2024

(54) CORE STRUCTURE OF INDUCTOR ELEMENT AND METHOD OF MANUFACTURING THE SAME

(71) Applicant: PHOENIX PIONEER TECHNOLOGY CO., LTD., Hsinchu County (TW)

(72) Inventors: Pao-Hung CHOU, Hsinchu County (TW); Che-Wei HSU, Hsinchu County (TW); Shih-Ping HSU, Hsinchu County (TW)

(73) Assignee: PHOENIX PIONEER TECHNOLOGY CO., LTD., Hsinchu County (TW)

(21) Appl. No.: 18/499,111

(22) Filed: Oct. 31, 2023

(30) Foreign Application Priority Data
Nov. 2, 2022 (TW) 111141853

(51) Int. Cl. H01F 27/26; H01F 41/18; H01F 41/26

(52) U.S. Cl. CPC H01F 27/263; H01F 41/18; H01F 41/26; H01L 28/10

(57) ABSTRACT

Provided is a core structure of an inductor element. The manufacturing method thereof is to embed a magnetic conductor including at least one magnetic conductive layer in a core body and to from a plurality of apertures for passing coils around the magnetic conductor in the core body. Accordingly, the magnetic conductor is designed in the core body by using the integrated circuit carrier board manufacturing process, such that the overall size and thickness of the inductor element can be greatly reduced, thereby facilitating product miniaturization using the inductor element.

### BACKGROUND

### 1. Technical Field

The present disclosure relates to an inductor element used in a semiconductor manufacturing process, and more particularly, to a core structure of an inductor element for a substrate-based inductor that can be embedded in a packaging substrate and the method of manufacturing the same.

### 2. Description of Related Art

In general semiconductor application devices, such as communication or high-frequency semiconductor devices, it is often necessary to electrically connect most radio-frequency passive elements (e.g., resistors, inductors, capacitors and oscillators) to a packaged semiconductor chip so as to make the semiconductor chip have specific current characteristics or send out signals. For example, there are many types of conventional inductors, which are mostly used to suppress power supply noise or perform DC-to-DC power conversion (direct current step-up or step-down).

At present, the semiconductor industry is aiming at miniaturization or thinning of a single element for an electronic device that is becoming thinner and smaller. In a semiconductor package 1 shown in FIG. 1A, a coil inductor 12 is integrated on a packaging substrate 10 having a circuit layer 11. A semiconductor chip 13 is arranged on the packaging substrate 10 and is electrically connected to bonding pads 110 of the circuit layer 11 by a plurality of bonding wires 130, wherein sputtering and vaporing techniques can be used to produce a thinner metal film to form the coil inductor 12, that is, a thin film inductor as shown in FIG. 1B.

However, the coil inductor 12 is disposed on the packaging substrate 10, such that the inductance value generated by the coil inductor 12 is too small to meet requirements.

Therefore, how to overcome various problems of the above-mentioned prior art has become a problem urgently to be overcome in the industry.

### SUMMARY

In view of the various deficiencies of the prior art, the present disclosure provides a core structure of an inductor element, the core structure comprises: a core body having a first side and a second side opposing the first side and a first aperture and a second aperture communicating with the first side and the second side; and a magnetic conductor embedded in the core body and configured with respect to the first aperture and the second aperture of the core body, wherein the first aperture and the second aperture of the core body are formed on opposite sides of the magnetic conductor, wherein the magnetic conductor includes at least one magnetic conductive layer.

The present disclosure also provides a method of manufacturing a core structure of an inductor element, the method comprises: forming a first insulating layer on a carrier; forming a magnetic conductive layer on the first insulating layer, wherein the magnetic conductive layer acts as a magnetic conductor; forming a second insulating layer on the first insulating layer to cover the magnetic conductive layer, wherein the first insulating layer and the second insulating layer serve as a core body, and the core body has a first side and a second side opposing the first side; removing the carrier to expose the first side of the core body; and forming a first aperture and a second aperture penetrating through the core body, wherein the first aperture and the second aperture communicate with the first side and the second side of the core body, wherein the magnetic conductor is configured with respect to the first aperture and the second aperture of the core body, and the first aperture and the second aperture of the core body are formed on opposite sides of the magnetic conductor.

In the aforementioned method, the present disclosure further comprises forming another magnetic conductive layer on the second insulating layer and subsequently forming a third insulating layer on the second insulating layer to cover the another magnetic conductive layer, wherein the core body comprises the third insulating layer, and the magnetic conductor comprises the another magnetic conductive layer.

In the aforementioned core structure and method, a material forming the core body is a dielectric material, such as Ajinomoto Build-up Film (ABF), photosensitive compound/resin, polyimide (PI), bismaleimide triazine (BT), flame resistant/retardant 5 (FR5) prepreg (PP) material, molding compound/resin, epoxy molding compound/resin (EMC) or other appropriate materials. The preferred material of the core body is PI, ABF or EMC which is easy for circuit processing.

In the aforementioned core structure and method, the magnetic conductor contains at least one of iron (Fe), nickel (Ni), cobalt (Co), manganese (Mn), zinc (Zn) or a combination thereof (a plurality of stacked metal layers), or an alloy material of a combination thereof, such as nickel/iron alloy, nickel/iron/cobalt alloy, zinc/nickel alloy or other alloys, or other magnetic substances, etc.

In the aforementioned core structure and method, the magnetic conductive layer is in a shape of a plane plate.

In the aforementioned core structure and method, the present disclosure further comprises forming a pattern layer on the magnetic conductive layer, wherein the magnetic conductive layer and the pattern layer are covered by the second insulating layer, and the magnetic conductor further comprises the pattern layer formed on the magnetic conductive layer.

In the aforementioned core structure and method, a top view shape of the magnetic conductive layer is a rectangular structure, a ring structure or a structure with a plurality of parallel slots in a rectangular outline.

In the aforementioned core structure and method, the core body further has at least one third aperture communicating with the first side and the second side, and the magnetic conductor is formed around the third aperture of the core body, wherein the first aperture, the second aperture and the third aperture are provided with multiple strands of wire to be wound to form inductive coils.

As can be seen from the above, in the core structure and the method of manufacturing the same of the present disclosure, the magnetic conductor is formed mainly by using a printed circuit board (PCB) or a carrier board to make patterned build-up circuits together with electroplating or deposition of magnetic conductive materials in the core body, such that the magnetic conductor can be adjusted and combined with the requirements of the applications to meet the electrical requirements. In addition, since the inductor element can be embedded in the carrier board, the production process can be reduced to reduce the cost. Moreover, because tiny inductor elements can be manufactured, the purpose of miniaturization or thinning of products can be achieved.

Further, by means of the design of the pattern layer, the influence of eddy current and magnetic loss on a Q value (where Q stands for quality or quality factor) can be reduced, thereby increasing the inductance value of the inductor element.

### BRIEF DESCRIPTION OF THE DRAWINGS

FIG. 1A is a schematic cross-sectional view of a conventional semiconductor package.

FIG. 1B is a schematic partial perspective view of FIG. 1A.

FIG. 2A is a schematic cross-sectional view showing a core structure of an inductor element according to a first embodiment of the present disclosure.

FIG. 2B to FIG. 2H are schematic cross-sectional views showing a method of manufacturing the core structure of the inductor element according to the first embodiment of the present disclosure.

FIG. 3A is a schematic cross-sectional view showing a core structure of an inductor element according to a second embodiment of the present disclosure.

FIG. 3B to FIG. 3H are schematic cross-sectional views showing a method of manufacturing the core structure of the inductor element according to the second embodiment of the present disclosure.

FIG. 3I is a schematic cross-sectional view showing another aspect of FIG. 3H.

FIG. 4A to FIG. 4C are schematic top plan views showing different aspects of the core structure of the inductor element according to the present disclosure.

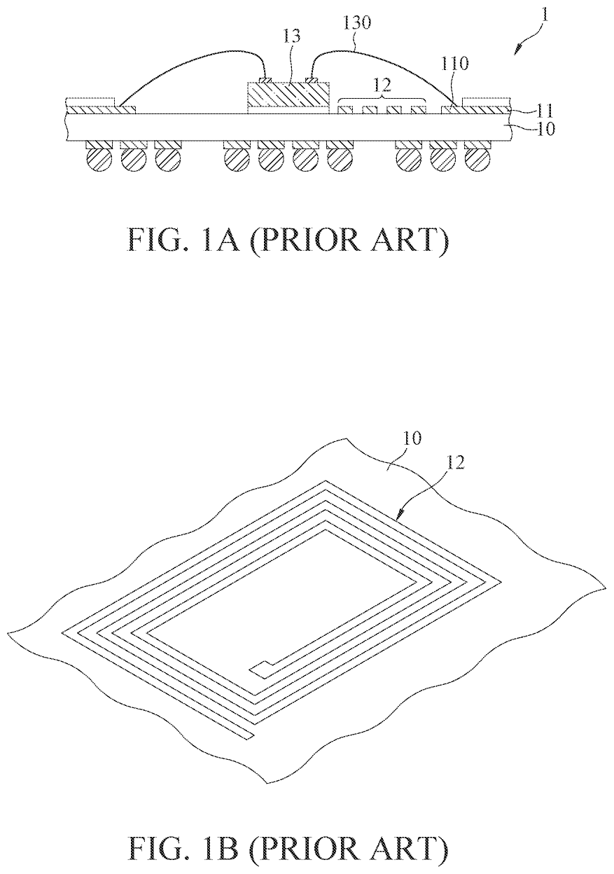

### DETAILED DESCRIPTIONS

The following describes the implementation of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “on,” “first,” “second,” “third,” “a,” “one” and the like used herein are merely used for clear explanation rather than limiting the practicable scope of the present disclosure, and thus, alterations or adjustments of the relative relationships thereof without essentially altering the technical contents should still be considered in the practicable scope of the present disclosure.

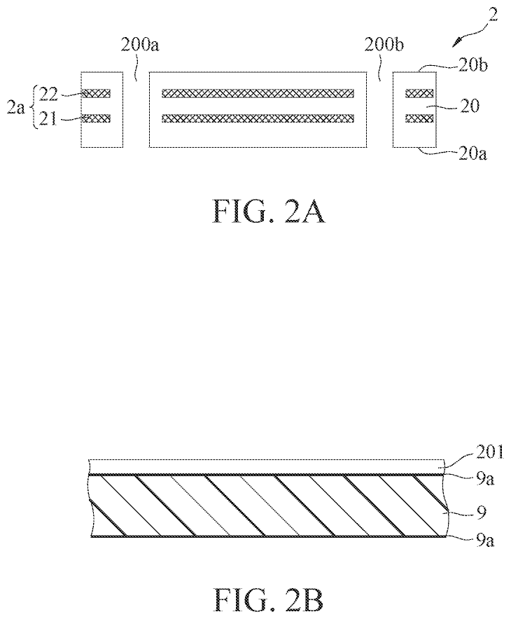

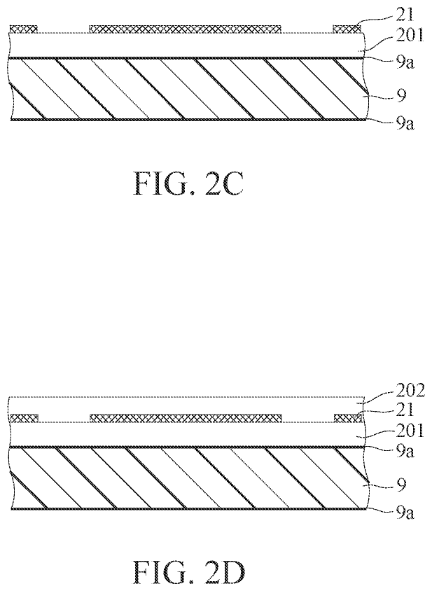

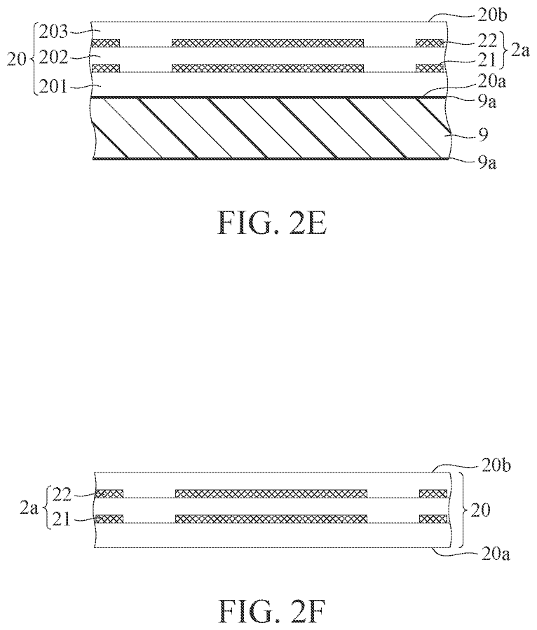

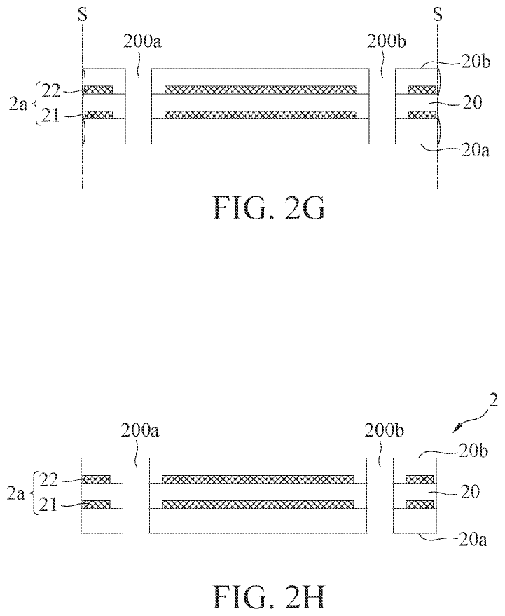

FIG. 2A is a schematic cross-sectional view showing a core structure 2 of an inductor element according to a first embodiment of the present disclosure. As shown in FIG. 2A, the core structure 2 includes a core body 20 and a magnetic conductor 2a embedded in the core body 20.

The core body 20 has a first side 20a and a second side 20b opposite to each other and a first aperture 200a and a second aperture 200b (e.g., opening slots) communicating with the first side 20a and the second side 20b.

In an embodiment, the core body 20 is made of a dielectric material, such as Ajinomoto Build-up Film (ABF), photosensitive compound/resin, polyimide (PI), bismaleimide triazine (BT), flame resistant/retardant 5 (FR5) prepreg (PP) material, molding compound/resin, epoxy molding compound/resin (EMC) or other appropriate materials. The preferred material of the core body 20 is PI, ABF or EMC which is easy for circuit processing.

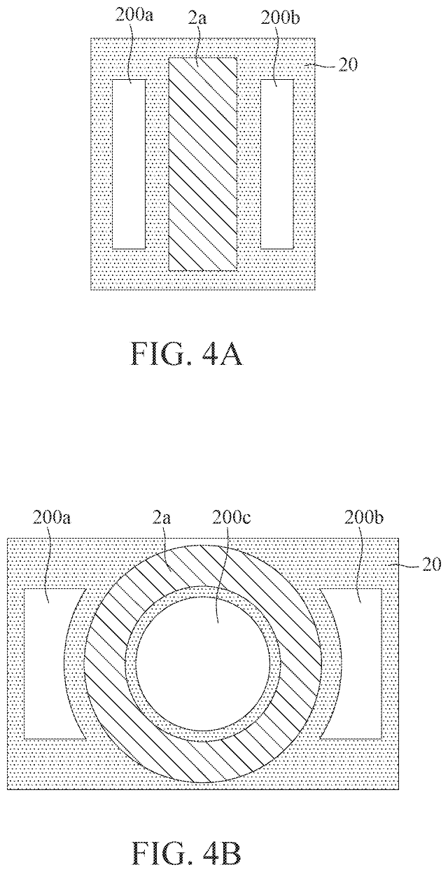

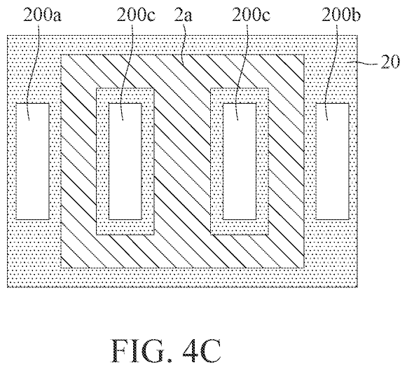

In addition, the first aperture 200a and the second aperture 200b of the core body 20 are formed on opposite sides (e.g., left and right sides) of the magnetic conductor 2a for passing coils (not shown), and the shape of the first aperture 200a and the second aperture 200b may be designed according to the pattern of the magnetic conductor 2a, as shown in FIG. 4A to FIG. 4C, but not limited thereto. In other words, the first aperture 200a and the second aperture 200b can be provided with multiple strands of wire to be wound to form inductive coils.

The magnetic conductor 2a is embedded in the core body 20 and configured with respect to the first aperture 200a and the second aperture 200b of the core body 20, wherein the magnetic conductor 2a includes at least one magnetic conductive layer 21, 22.

In an embodiment, the magnetic conductor 2a is made by means of electroplating, sputtering or physical vapor deposition (PVD), etc., and the magnetic conductor 2a contains at least one of iron (Fe), nickel (Ni), cobalt (Co), manganese (Mn), zinc (Zn) or a combination thereof (a plurality of stacked metal layers), or an alloy material of a combination thereof, such as nickel/iron alloy, cobalt/nickel/iron alloy, zinc/nickel alloy or other alloys, or other magnetic substances, etc.

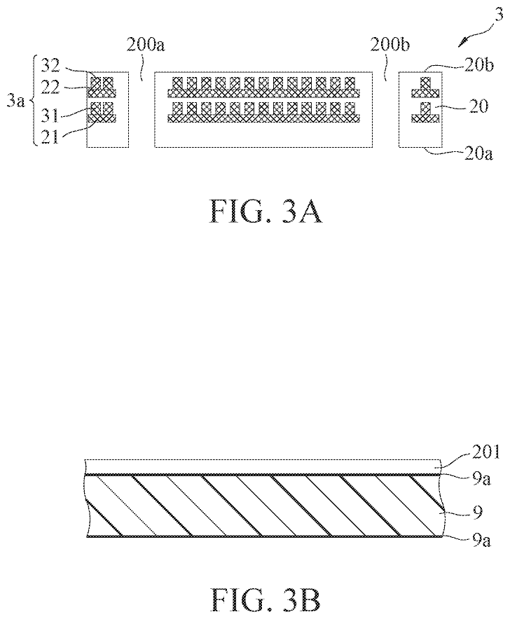

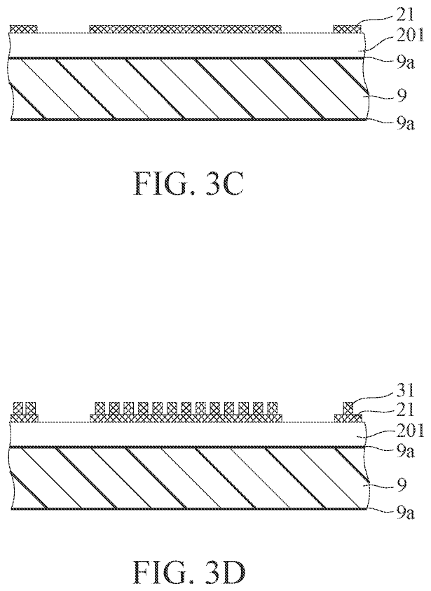

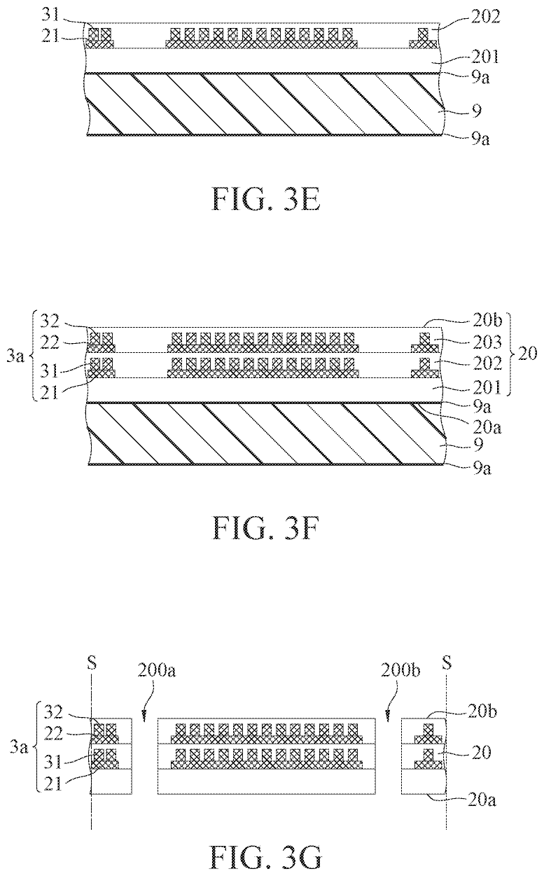

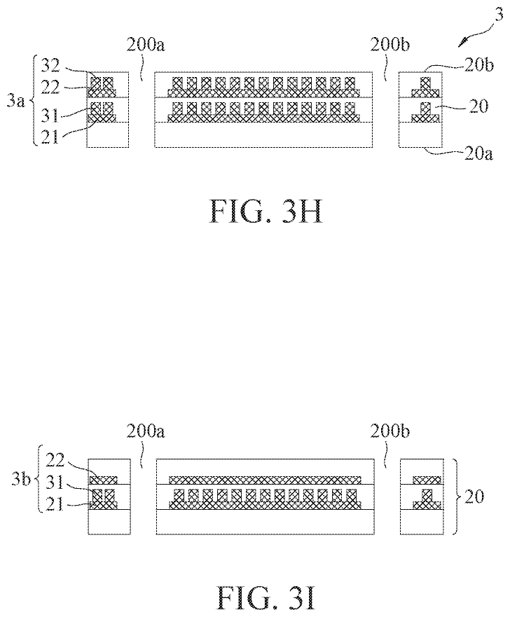

Moreover, the magnetic conductor 2a may be planar magnetic conductive layers 21, 22. Alternatively, as shown in a core structure 3 of FIG. 3A, a magnetic conductor 3a may also include pattern layers 31, 32 formed on the magnetic conductive layers 21, 22 respectively to reduce the eddy current effect and increase inductance value.

Further, the pattern layers 31, 32 are made by means of electroplating, sputtering or physical vapor deposition (PVD), etc., and the pattern layers 31, 32 contain at least one of iron (Fe), nickel (Ni), cobalt (Co), manganese (Mn), zinc (Zn) or a combination thereof (a plurality of stacked metal layers), or an alloy material of a combination thereof, such as nickel/iron alloy, cobalt/nickel/iron alloy, zinc/nickel alloy or other alloys, or other magnetic substances, etc. It should be understood that the materials of the pattern layers 31, 32 and the magnetic conductive layers 21, 22 may be the same or different.

In addition, a top view shape of the magnetic conductive layers 21, 22 of the magnetic conductors 2a, 3a may be a rectangular structure (as shown in FIG. 4A), a ring structure (as shown in FIG. 4B) or a structure with a plurality of parallel slots in a rectangular outline (as shown in FIG. 4C). In the embodiments of FIG. 4B and FIG. 4C, the core body 20 may have at least one (e.g., one or two) third aperture 200c communicating with the first side 20a and the second side 20b, and the magnetic conductor 2a, 3a is formed around the third aperture 200c of the core body 20.

Therefore, in the core structure 2, 3 of the present disclosure, the magnetic conductive alloy metal material (e.g., the magnetic conductors 2a, 3a) is embedded in the core body 20 by the carrier board technology when making inductor elements, such that a plurality of inductive coils are formed in the first aperture 200a, the second aperture 200b and/or the third aperture 200c to serve as an inductor body. Accordingly, a magnetic conductor 2a is arranged in the middle of the inductive coil as a magnetic core, which can obtain an inductor element with a large magnetic flux (i.e., a combination of the inductor body and the magnetic conductor 2a) so as to meet the needs of larger inductance values or thinner inductors. Besides, the first aperture 200a, the second aperture 200b and the third aperture 200c can be provided with multiple strands of wire to be wound to form inductive coils.

FIG. 2B to FIG. 2H are schematic cross-sectional views showing a method of manufacturing a core structure 2 of an inductor element according to the first embodiment of the present disclosure.

As shown in FIG. 2B, a first insulating layer 201 is formed on a carrier 9.

In an embodiment, the carrier 9 is made of a removable substrate material, such as a cooper foil substrate, a metal plate or a combination of a metal plate and an insulating material, but not limited thereto. In an embodiment, the carrier 9 is illustrated by a metal plate combined with an insulating material, and there are copper-containing metal materials 9a on both sides of the carrier 9.

Furthermore, the first insulating layer 201 is made of a dielectric material, such as Ajinomoto Build-up Film (ABF), photosensitive compound/resin, polyimide (PI), bismaleimide triazine (BT), flame resistant/retardant 5 (FR5) prepreg (PP) material, molding compound/resin, epoxy molding compound/resin (EMC) or other appropriate materials. The preferred material of the first insulating layer 201 is PI, ABF or EMC which is easy for circuit processing.

As shown in FIG. 2C, a magnetic conductive layer 21 is formed on the first insulating layer 201.

In an embodiment, the magnetic conductive layer 21 is made by means of electroplating, sputtering or physical vapor deposition (PVD), etc., and the magnetic conductive layer 21 contains at least one of iron (Fe), nickel (Ni), cobalt (Co), manganese (Mn), zinc (Zn) or a combination thereof (a plurality of stacked metal layers), or an alloy material of a combination thereof, such as nickel/iron alloy, cobalt/nickel/iron alloy, zinc/nickel alloy or other alloys, or other magnetic substances, etc.

As shown in FIG. 2D, a second insulating layer 202 is formed on the first insulating layer 201 to cover the magnetic conductive layer 21.

In an embodiment, the second insulating layer 202 is made of a dielectric material, such as Ajinomoto Build-up Film (ABF), photosensitive compound/resin, polyimide (PI), bismaleimide triazine (BT), flame resistant/retardant 5 (FR5) prepreg (PP) material, molding compound/resin, epoxy molding compound/resin (EMC) or other appropriate materials. The preferred material of the second insulating layer 202 is PI, ABF or EMC which is easy for circuit processing.

As shown in FIG. 2E, another magnetic conductive layer 22 is formed on the second insulating layer 202, and a third insulating layer 203 is subsequently formed on the second insulating layer 202 to cover the magnetic conductive layer 22, such that the first insulating layer 201, the second insulating layer 202 and the third insulating layer 203 serve as a core body 20, and the magnetic conductive layers 21, 22 form a magnetic conductor 2a.

In an embodiment, the core body 20 has a first side 20a and a second side 20b opposite to each other, and the core body 20 is bonded onto the carrier 9 via the first side 20a thereof.

In addition, the magnetic conductive layer 22 may be made by means of electroplating, sputtering or physical vapor deposition (PVD), etc., and the magnetic conductive layer 22 contains at least one of iron (Fe), nickel (Ni), cobalt (Co), manganese (Mn), zinc (Zn) or a combination thereof (a plurality of stacked metal layers), or an alloy material of a combination thereof, such as nickel/iron alloy, cobalt/nickel/iron alloy, zinc/nickel alloy or other alloys, or other magnetic substances, etc.

Moreover, the third insulating layer 203 is made of a dielectric material, such as Ajinomoto Build-up Film (ABF), photosensitive compound/resin, polyimide (PI), bismaleimide triazine (BT), flame resistant/retardant 5 (FR5) prepreg (PP) material, molding compound/resin, epoxy molding compound/resin (EMC) or other appropriate materials. The preferred material of the third insulating layer 203 is PI, ABF or EMC which is easy for circuit processing.

It should be understood that the number of layers of the magnetic conductor 2a can be designed according to requirements, such as three or more magnetic conductive layers. As such, the process shown in FIG. 2E can be repeated to make the number of layers of the magnetic conductor 2a meet the requirements.

As shown in FIG. 2F, the carrier 9 is removed and the metal material 9a thereof is etched to expose the first side 20 of the core body 20.

As shown in FIG. 2G, a first aperture 200a and a second aperture 200b penetrating through the core body 20 are formed, such that the first aperture 200a and the second aperture 200b communicate with the first side 20a and the second side 20b of the core body 20.

In an embodiment, according to various graphic/shape requirements, as shown in FIG. 4A to FIG. 4C, apertures are made around the magnetic conductor 2a for subsequent copper coils to be wound. For example, a coil (not shown) of the inductor element may be a spiral coil, a solenoid coil, or a toroid coil, but not limited thereto.

As shown in FIG. 2H, a singulation process is performed along the cutting path S shown in FIG. 2G to obtain the core structure 2.

Therefore, the manufacturing method of the present disclosure is to embed the magnetic conductor 2a with the magnetic conductive layers in the core body 20 when making inductor elements and to subsequently form a plurality of inductive coils in the first aperture 200a, the second aperture 200b and/or the third aperture 200c to serve as an inductor body. Accordingly, a magnetic conductor 2a is arranged in the middle of the inductive coil to form a larger cross-sectional area, such that an inductor element with a large magnetic flux is obtained and the requirements of larger inductance values or thinner inductors are met.

FIG. 3B to FIG. 3I are schematic cross-sectional views showing a method of manufacturing a core structure 3 of an inductor element according to the present disclosure. The difference between this embodiment and the first embodiment lies in the manufacturing process of newly added pattern layers 31, 32. Hence, the similarities will not be repeated below.

As shown in FIG. 3B, a first insulating layer 201 is formed on a carrier 9.

As shown in FIG. 3C, a magnetic conductive layer 21 is formed on the first insulating layer 201.

As shown in FIG. 3D, a pattern layer 31 is formed on the magnetic conductive layer 21.

In an embodiment, the pattern layer 31 is made by means of electroplating, sputtering or physical vapor deposition (PVD), etc., and the pattern layer 31 contains at least one of iron (Fe), nickel (Ni), cobalt (Co), manganese (Mn), zinc (Zn) or a combination thereof (a plurality of stacked metal layers), or an alloy material of a combination thereof, such as nickel/iron alloy, cobalt/nickel/iron alloy, zinc/nickel alloy or other alloys, or other magnetic substances, etc.

As shown in FIG. 3E, a second insulating layer 202 is formed on the first insulating layer 201 to cover the magnetic conductive layer 21 and the pattern layer 31 thereon.

As shown in FIG. 3F, another magnetic conductive layer 22 is formed on the second insulating layer 202, and another pattern layer 32 is subsequently formed on the magnetic conductive layer 22. After that, a third insulating layer 203 is formed on the second insulating layer 202 to cover the magnetic conductive layer 22 and the pattern layer 32 thereon, such that the first insulating layer 201, the second insulating layer 202 and the third insulating layer 203 are served as the core body 20, and the magnetic conductive layers 21, 22 and the pattern layers 31, 32 thereon constitute the magnetic conductor 3a.

In an embodiment, the pattern layer 32 may be made by means of electroplating, sputtering or physical vapor deposition (PVD), etc., and the pattern layer 32 contains at least one of iron (Fe), nickel (Ni), cobalt (Co), manganese (Mn), zinc (Zn) or a combination thereof (a plurality of stacked metal layers), or an alloy material of a combination thereof, such as nickel/iron alloy, cobalt/nickel/iron alloy, zinc/nickel alloy or other alloys, or other magnetic substances, etc.

As shown in FIG. 3G, the carrier 9 is removed and the metal material 9a thereof is etched to expose the first side 20a of the core body 20. Subsequently, a first aperture 200a and a second aperture 200b penetrating through the core body 20 are formed, such that the first aperture 200a and the second aperture 200b communicate with the first side 20a and the second side 20b. In other words, the first aperture 200a and the second aperture 200b can be provided with multiple strands of wire to be wound to form inductive coils.

In an embodiment, the patterning of the magnetic conductor 3a may be planar, toothed, triangular, cylindrical or a combination of other shapes and may be continuous, segmented or a combination thereof, but not limited thereto.

As shown in FIG. 3H, a singulation process is performed along the cutting path S shown in FIG. 3G to obtain the core structure 3.

Therefore, the manufacturing method of the present disclosure is to form the magnetic conductive materials on the magnetic conductive layers 21, 22 in a patterned manner by electroplating when making the magnetic conductor 3a, such that the magnetic conductive materials serve as the pattern layers 31, 32. Accordingly, in subsequent applications, inductor elements with larger magnetic flux can be obtained.

It should be understood that the aspect of each layer of the magnetic conductor can be designed according to requirements. For example, a pattern layer 31 is formed on at least one magnetic conductive layer 21, while no pattern layer is formed on the other magnetic conductive layer 22, such that a hybrid magnetic conductor 3b can be formed, as shown in FIG. 3I.

To sum up, in the core structure 2, 3 and the manufacturing method thereof of the present disclosure, the magnetic conductor 2a, 3a, 3b is formed in the core body 20 by utilizing the integrated circuit (IC) carrier board manufacturing process so as to obtain a flat/thin inductor element, thereby achieving the purpose of product miniaturization or thinning.

In addition, by using the alloy metal with high magnetic permeability together with the manufacturing method of the carrier board, it is easy to use the magnetic conductive material and the insulating layers (e.g., the first insulating layer 201, the second insulating layer 202 and the third insulating layer 203) for patterning process, such that the core structure 2, 3 facilitates various designs and applications.

Moreover, the magnetic permeability of the magnetic conductors 2a, 3a can be controlled by electroplating or deposition to control the appropriate composition ratio, so as to obtain appropriate magnetic permeability.

Further, with the configuration of the pattern layers 31, 32, the influence of eddy current and magnetic loss on the Q value can be reduced, and the inductance value can be increased.

Furthermore, the core body 20 of the core structure 2, 3 of the present disclosure is easy to manufacture and does not need to be doped with magnetic powder, such that the manufacturing method of the present disclosure can reduce the production cost, thereby meeting the requirement of economic benefit for the inductor element.

The foregoing embodiments are provided for the purpose of illustrating the principles and effects of the present disclosure, rather than limiting the present disclosure. Anyone skilled in the art can modify and alter the above embodiments without departing from the spirit and scope of the present disclosure. Therefore, the scope of protection with regard to the present disclosure should be as defined in the accompanying claims listed below.

What is claimed is:

1. A core structure of an inductor element, the core structure comprising:
a core body having a first side and a second side opposing the first side and a first aperture and a second aperture communicating with the first side and the second side; and
a magnetic conductor embedded in the core body and configured with respect to the first aperture and the second aperture of the core body, wherein the first aperture and the second aperture of the core body are formed on opposite sides of the magnetic conductor, wherein the magnetic conductor includes at least one magnetic conductive layer.

2. The core structure of claim 1, wherein a material forming the core body is a photosensitive or non-photosensitive insulating material and includes Ajinomoto Build-up Film, photosensitive compound, polyimide, bismaleimide triazine, flame resistant 5 prepreg material, molding compound, or epoxy molding compound.

3. The core structure of claim 1, wherein the magnetic conductor contains at least one of iron, nickel, cobalt, manganese, zinc or a combination thereof, or an alloy material of a combination thereof, including nickel/iron alloy, cobalt/nickel/iron alloy or zinc/nickel alloy.

4. The core structure of claim 1, wherein the magnetic conductive layer is in a shape of a plane plate.

5. The core structure of claim 1, wherein the magnetic conductor further comprises a pattern layer formed on the magnetic conductive layer, and the pattern layer comprises teeth, triangles, cylinders or a combination of other shapes and is continuous, segmented or a combination thereof.

6. The core structure of claim 1, wherein a top view shape of the magnetic conductive layer is a rectangular structure, a ring structure or a structure with a plurality of parallel slots in a rectangular outline.

7. The core structure of claim 1, wherein the core body further has at least one third aperture communicating with the first side and the second side, and the magnetic conductor is formed around the third aperture of the core body.

8. A method of manufacturing a core structure of an inductor element, the method comprising:
forming a first insulating layer on a carrier;
forming a magnetic conductive layer on the first insulating layer, wherein the magnetic conductive layer acts as a magnetic conductor;
forming a second insulating layer on the first insulating layer to cover the magnetic conductive layer, wherein the first insulating layer and the second insulating layer serve as a core body, and the core body has a first side and a second side opposing the first side;
removing the carrier to expose the first side of the core body; and
forming a first aperture and a second aperture penetrating through the core body, wherein the first aperture and the second aperture communicate with the first side and the second side of the core body, wherein the magnetic conductor is configured with respect to the first aperture and the second aperture of the core body, and the first aperture and the second aperture of the core body are formed on opposite sides of the magnetic conductor.

9. The method of claim 8, wherein the magnetic conductive layer is formed by electroplating, sputtering or physical vapor deposition.

10. The method of claim 8, further comprising forming another magnetic conductive layer on the second insulating layer and subsequently forming a third insulating layer on the second insulating layer to cover the another magnetic conductive layer, wherein the core body comprises the third insulating layer, and the magnetic conductor comprises the another magnetic conductive layer.

11. The method of claim 8, wherein a material forming the core body is a photosensitive or non-photosensitive insulating material and includes Ajinomoto Build-up Film, photosensitive compound, polyimide, bismaleimide triazine, flame resistant 5 prepreg material, molding compound, or epoxy molding compound.

12. The method of claim 8, wherein the magnetic conductor contains at least one of iron, nickel, cobalt, manganese, zinc or a combination thereof, or an alloy material of a combination thereof, including nickel/iron alloy, cobalt/nickel/iron alloy or zinc/nickel alloy.

13. The method of claim 8, wherein the magnetic conductive layer is in a shape of a plane plate.

14. The method of claim 8, further comprising forming a pattern layer on the magnetic conductive layer, wherein the magnetic conductive layer and the pattern layer are covered by the second insulating layer.

15. The method of claim 8, wherein a top view shape of the magnetic conductive layer is a rectangular structure, a ring structure or a structure with a plurality of parallel slots in a rectangular outline.

16. The method of claim 8, wherein the core body is formed with at least one third aperture communicating with the first side and the second side, and the magnetic conductor is formed around the third aperture of the core body.
